(19) United States
(12) Patent Application Publication
(10) Pub. No.: US 2023/0207266 A1
(43) Pub. Date: Jun. 29, 2023

(54) SUBSTRATE PROCESSING APPARATUS, HARMONIC CONTROL UNIT AND HARMONIC CONTROL METHOD

(71) Applicant: SEMES CO., LTD., Cheonan-si (KR)

(72) Inventors: Ja Myung GU, Cheonan-si (KR); Hyung Joon KIM, Pyeongtaek-si (KR); Sae Won NA, Cheongju-si (KR)

(73) Assignee: SEMES CO., LTD., Cheonan-si (KR)

(21) Appl. No.: 18/147,382

(22) Filed: Dec. 28, 2022

(30) Foreign Application Priority Data
Dec. 29, 2021 (KR) 10-2021-0191633

(51) Int. Cl. H01J 37/32

(52) U.S. Cl. CPC H01J 37/32174; H01J 37/32642; H01J 37/32715

(57) ABSTRACT

Disclosed is a substrate processing apparatus. The substrate processing apparatus includes a chamber having an inner space; a support unit that supports a substrate in the inner space; a ring unit disposed on an edge area of the support unit when viewed from above; a power unit that generates RF power for forming an electric field in the inner space; and a harmonic control unit connected to the ring unit to control harmonics generated by the RF power.

### CROSS-REFERENCE TO RELATED APPLICATIONS

A claim for priority under 35 U.S.C. § 119 is made to Korean Patent Application No. 10-2021-0191633 filed on Dec. 29, 2021, in the Korean Intellectual Property Office, the entire contents of which are hereby incorporated by reference.

### BACKGROUND

Embodiments of the inventive concept described herein relate to a substrate processing apparatus, a harmonic control unit, and a harmonics control method.

In order to manufacture a semiconductor device, a substrate is subjected to various processes such as photolithography, etching, ashing, ion implantation, thin film deposition, and cleaning to form a desired pattern on the substrate. Among them, the etching process is a process of removing a selected heating region from among the films formed on the substrate, and wet etching and dry etching are used. Among them, an etching device using plasma is used for dry etching. Plasma refers to an ionized gaseous state composed of ions, electrons, or radicals. Plasma is generated by very high temperatures or strong RF Electromagnetic Fields. In the high-frequency electromagnetic field, an RF generator applies an RF voltage to one of electrodes facing to each other. The RF power applied by the RF generator excites the process gas supplied into a chamber to generate plasma. As the height of a semiconductor stack such as 3D NAND flash increases year by year, the etching of a high stack structure increases the plasma process time. The process time is shortened by increasing the RF power applied by the RF generator to naturally increase the plasma density.

Meanwhile, in the chamber, harmonics may be generated due to the nonlinear impedance of the structure of the chamber, an external circuit, plasma, and a plasma sheath. The harmonics may be a wave having a frequency that is an integer multiple of the main frequency of the RF voltage applied by the RF generator. As shown in FIG. 1, the generated harmonics may propagate from the edge of the substrate to the center of the substrate in the form of a surface wave along the surface of the substrate such as a wafer. In this case, the wavelength of the surface wave is expressed as follows.

$$\approx λ \approx \frac{{λ}_{0}}{\sqrt{1 + d / s}}$$

Where λ is the wavelength of the surface wave, λ₀ is the wavelength in vacuum, d is a plasma thickness, S is the thickness of the plasma sheath, and L is the electrode diameter.

According to some documents, harmonic components propagating under the condition of λ≤L may overlap so that a standing wave is generated.

As described above, when the frequency of the voltage generated by the RF generator is high, the frequency of a harmonic component may also be high. In the case of a harmonic component having a high frequency, the wavelength λ₀ in vacuum may be reduced, and meet the standing wave generation condition. The effect of transferring the intensity of a standing wave to the plasma density may be called standing wave effect (SWE), by which the plasma density increases at a place where the strength of the standing wave is strong and the plasma density decreases at a place where the strength of the standing wave is low. Uniformity of plasma density may be deteriorated by SWE. In other words, uniformity of substrate processing by plasma may deteriorate due to harmonics generated in the chamber. As described above, recently, the intensity of the RF power may be increased to increase the plasma density. As the strength of the RF power increases, the strength of the harmonic component also increases, and thus uniformity of substrate processing may be further deteriorated.

In order to suppress such harmonics, a scheme of changing a resonant frequency region of a chamber in which harmonics are amplified by connecting an external circuit to an electrostatic chuck to which an RF generator applies RF power may be considered. In this case, it is a principle to prevent the intensity of the generated harmonic component from being amplified any longer and affecting the plasma density. However, in this case, the transfer characteristics of the RF power applied to the electrostatic chuck may be affected. In addition, the plasma process proceeds in dozens of steps, and the resonant frequency of the above-described chamber may vary depending on the plasma generated in each step. In other words, since conditions for amplifying harmonics may vary in each step, it is necessary to control the above-described external circuit to change the resonant frequency region of the chamber in each step.

In addition, depending on conditions, not a single harmonic component but two or more harmonic components in the electric field may affect the plasma density. In other words, because control of only one harmonic component is not sufficient to improve plasma uniformity, control of two or more harmonic components is required.

### SUMMARY

Embodiments of the inventive concept provide a substrate processing apparatus capable of efficiently processing a substrate, a harmonic control unit, and a harmonics control method.

In addition, embodiments of the inventive concept provide a substrate processing apparatus, a harmonic control unit, and a harmonics control method capable of improving substrate processing uniformity by plasma.

In addition, embodiments of the inventive concept provide a substrate processing apparatus, a harmonic control unit, and a harmonics control method capable of effectively controlling harmonic components in an electric field generated in an inner space of a chamber.

In addition, embodiments of the inventive concept provide a substrate processing apparatus, a harmonic control unit, and a harmonics control method capable of removing harmonic components in an electric field generated in an inner space of a chamber.

Objects of the inventive concept may not be limited to the above, and other objects will be clearly understandable to those having ordinary skill in the art from the disclosures provided below together with accompanying drawings.

According to an embodiment, a substrate processing apparatus includes a chamber having an inner space; a support unit that supports a substrate in the inner space; a ring unit disposed on an edge area of the support unit when viewed from above; a power unit that generates RF power for forming an electric field in the inner space; and a harmonic control unit connected to the ring unit to control harmonics generated by the RF power.

According to an embodiment, the ring unit may include an edge ring disposed to overlap an edge area of the substrate supported by the support unit when viewed from above; and a coupling ring disposed below the edge ring, wherein the harmonic control unit may be connected to the coupling ring.

According to an embodiment, the coupling ring may include a ring electrode; and a ring body formed of an insulating material and surrounding at least a portion of the ring electrode, wherein the harmonic control unit may be electrically connected to the ring electrode.

According to an embodiment, the harmonic control unit may include a blocking unit that blocks a frequency component of the RF power from flowing toward a ground; and a removal unit provided between the blocking unit and the ground to remove the harmonics.

According to an embodiment, the removal unit may include a first blocking filter that blocks frequency components other than a frequency component of a p-th harmonic among the harmonics; and a first harmonic control circuit provided between the first blocking filter and the ground.

According to an embodiment, the removal unit may include a second blocking filter that blocks frequency components other than a frequency component of a q-th harmonic different from the p-th harmonic, among the harmonics; and a second harmonic control circuit provided between the second blocking filter and the ground.

According to an embodiment, the first harmonic control circuit may include a first inductor and a first capacitor, and the second harmonic control circuit may include a second inductor and a second capacitor.

According to an embodiment, the substrate processing apparatus may further include a controller that controls the harmonic control unit, wherein the first capacitor and the second capacitor are variable capacitors, and the controller may adjust capacitances of the first capacitor and the second capacitor to allow the first harmonic control circuit to constitute a resonance circuit at a frequency of the p-th harmonic and allow the second harmonic control circuit to constitute a resonance circuit at a frequency of the q-th harmonic.

According to an embodiment, the substrate processing apparatus may further include a detection unit that detects a voltage or current flowing toward or to the harmonic control unit.

According to an embodiment, the controller may adjust at least one of the capacitances of the first capacitor and the second capacitor based on the voltage or current measured by the detection unit.

According to an embodiment, the power unit may include a first power source that applies a first voltage having a first frequency to an electrode forming the electric field; a second power source that applies a second voltage having a second frequency lower than the first frequency to the electrode; and a third power source that applies a third voltage having a third frequency lower than the first frequency and the second frequency to the electrode.

According to an embodiment, the blocking unit may include a first blocking filter that blocks a first frequency component of the first voltage; a second blocking filter that blocks a second frequency component of the second voltage; and a third blocking filter that blocks a third frequency component of the third voltage.

According to another embodiment, a harmonic control unit, that controls harmonics generated in a substrate processing apparatus and is connected to a conductive component, wherein the substrate processing apparatus includes an electrode that forms an electric field and the conductive component that is installed at a location different from a location of the electrode, includes a blocking unit that blocks a frequency component of RF power from flowing to a ground, the frequency component of the RF power forming the electric field among frequency components flowing into the harmonic control unit; and a removal unit provided between the blocking unit and the ground to remove the harmonics.

According to an embodiment, the removal unit may include a first harmonic removal unit; and a second harmonic removal unit that removes a frequency component different from a frequency component of the first harmonics removal unit.

According to an embodiment, the first harmonic removal unit may include a first blocking filter that blocks frequency components other than a frequency component of a p-th harmonic among the harmonics; and a first harmonic control circuit provided between the first blocking filter and the ground, wherein the second harmonic removal unit may include a second blocking filter that blocks frequency components other than a frequency component of a q-th harmonic different from the p-th harmonic, among the harmonics; and a second harmonic control circuit provided between the second blocking filter and the ground.

According to an embodiment, the first harmonic control circuit and the second harmonic control circuit may include a first capacitor and a second capacitor, respectively, wherein the first capacitor and the second capacitor are variable capacitors, and capacitances of the first capacitor and the second capacitor may be adjusted to allow the first harmonic control circuit to constitute a resonance circuit at a frequency of the p-th harmonic and allow the second harmonic control circuit to constitute a resonance circuit at a frequency of the q-th harmonic.

According to still another embodiment, a method of controlling harmonics generated in a chamber processing a substrate using plasma includes blocking, by a blocking unit of a harmonic control unit, a frequency component of RF power applied to an electrode forming an electric field in the chamber from flowing to a ground, wherein the harmonic control unit is connected to a ring unit disposed on an edge area of a support unit supporting the substrate; and removing the harmonics that passes through the blocking unit through a removal unit of the harmonic control unit, wherein the removing of the harmonics may include blocking frequency components other than the frequency components of the harmonics, and removing the harmonics through a harmonic control circuit having a variable capacitor.

According to an embodiment, the method may further include adjusting a capacitance of the variable capacitor to allow the harmonic control circuit to constitute a resonance circuit at a frequency of the harmonics.

According to an embodiment, the removing of the harmonics may include blocking frequency components other than a frequency component of a p-th harmonic among the harmonics through a first blocking filter; and removing the p-th harmonic through a first harmonic control circuit that constitutes a resonance circuit at a frequency of the p-th harmonic.

According to an embodiment, the removing of the harmonics through the removal unit may include blocking, through a second blocking filter, frequency components other than a frequency component of a q-th harmonic different from the p-th harmonic, among the harmonics; and removing the q-th harmonic through a second harmonic control circuit that is different from the first harmonic control circuit that constitutes a resonant circuit at a frequency of the q-th harmonic.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a diagram schematically illustrating the propagation of surface waves generated by harmonics;

FIG. 2 is a diagram illustrating a substrate processing apparatus according to an embodiment of the inventive concept;

FIG. 3 is a diagram schematically illustrating the harmonic control unit of FIG. 2;

FIG. 4 is a diagram schematically illustrating a first harmonic removal unit of FIG. 3;

FIG. 5 is a diagram showing a frequency condition in which maximum current flows into the first harmonic control circuit of FIG. 4;

FIG. 6 is a diagram schematically illustrating the appearances of a harmonic control unit and a detection unit of a substrate processing apparatus according to another embodiment of the inventive concept;

FIG. 7 is a graph illustrating changes in current of harmonic components detected by the detection unit of FIG. 6;

FIG. 8 is a diagram schematically illustrating the appearance of a harmonic control unit and a detection unit of a substrate processing apparatus according to another embodiment of the inventive concept;

FIG. 9 is a diagram illustrating the appearance of a substrate processing apparatus according to another embodiment of the inventive concept; and

FIG. 10 is a diagram schematically illustrating another example of the first harmonic removal unit of FIG. 3.

### DETAILED DESCRIPTION

Advantages and features of embodiments of the inventive concept, and method for achieving thereof will be apparent with reference to the accompanying drawings and detailed description that follows. But, it should be understood that the inventive concept is not limited to the following embodiments and may be embodied in different ways, and that the embodiments are given to provide complete disclosure of the inventive concept and to provide thorough understanding of the inventive concept to those skilled in the art, and the scope of the inventive concept is limited only by the accompanying claims and equivalents thereof.

Even though it is not defined, all terms (including technical or scientific terms) used herein have the same meanings as those belonging to the inventive concept is generally accepted by common techniques in the art. The terms defined in general dictionaries may be construed as having the same meanings as those used in the related art and/or a text of the present application and even when some terms are not clearly defined, they should not be construed as being conceptual or excessively formal.

The terms used in the present specification are provided to describe embodiments, not intended to limit it. In the present specification, singular forms are intended to include plural forms unless the context clearly indicates otherwise. It will be further understood that the terms “includes,” “including,” “comprises,” and/or “comprising,” used herein, specify the presence of stated features, integers, steps, operations, elements, and/or components, but do not preclude the presence or addition of one or more other features, integers, steps, operations, elements, components, and/or groups thereof. In the present disclosure, the term “and/or” indicates each of listed components or various combinations thereof.

The terms first, second, etc. may be used to describe various elements, but the elements should not be limited by the terms. The terms may be used only for the purpose of distinguishing one component from another component. For example, without departing from the scope of the inventive concept, a first component may be referred to as a second component. Similarly, the second component may also be referred to as a first component. Similarly, the second component may also be referred to as a first component.

Singular forms are intended to include plural forms unless the context clearly indicates otherwise. In addition, the shapes and the sizes of the components shown in the drawings may be exaggerated for clarity of explanation.

The term “unit” or “module”, as used in the specification, refers to software or a hardware component, such as an FPGA or ASIC, which perform functions. However, the term “unit” or “module” is not limited to software or hardware. The “unit” or “module” may be configured to be included in an addressable storage medium and to play one or more processors.

As an example, the term “unit” or “module” includes components, such as software components, object-oriented software components, class components, and task components, processes, functions, attributes, procedures, subroutines, segments of a program code, drivers, firmware, microcode, circuit, data, database, data structures, tables, arrays, and variables. Functions provided in components and “unit” or “module” may be engaged by a smaller number of components and “unit” or “module”, or may be divided into additional components and “unit” or “module”.

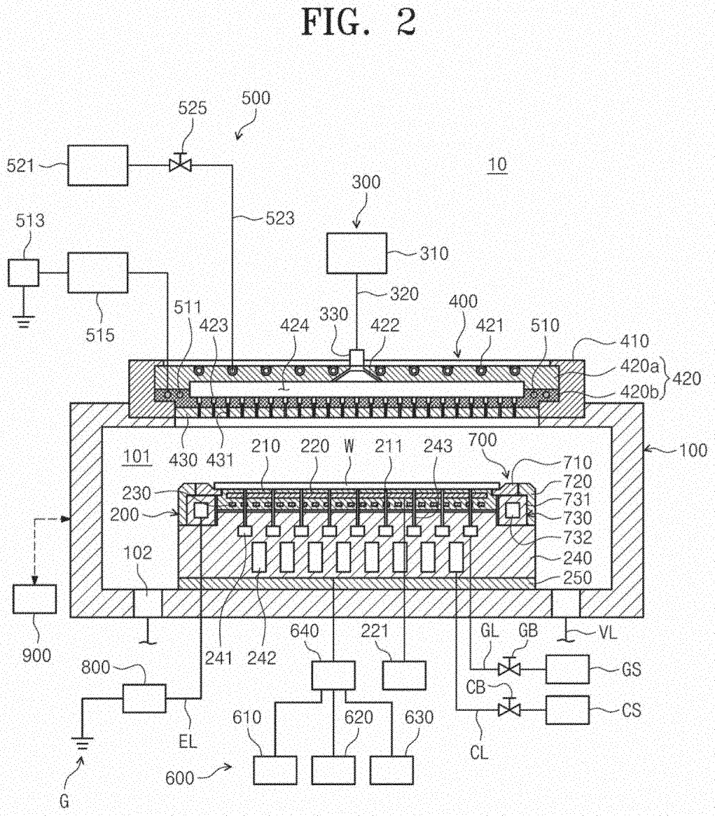

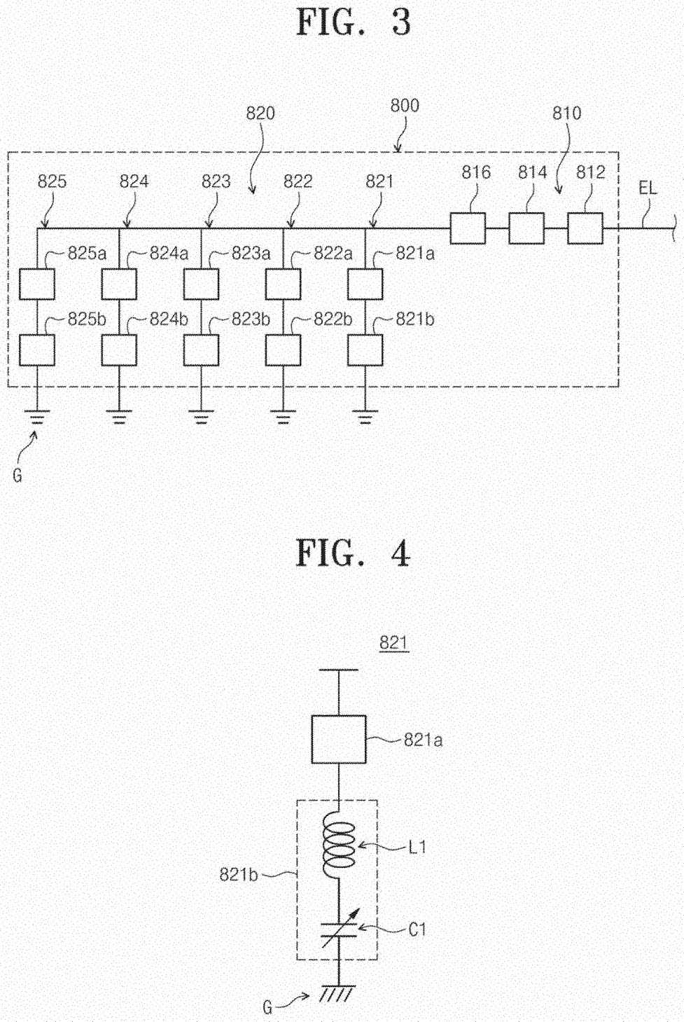

Hereinafter, an embodiment of the inventive concept will be described with reference to FIGS. 2 to 10.

FIG. 2 is a diagram schematically illustrating a substrate processing apparatus according to an embodiment of the inventive concept.

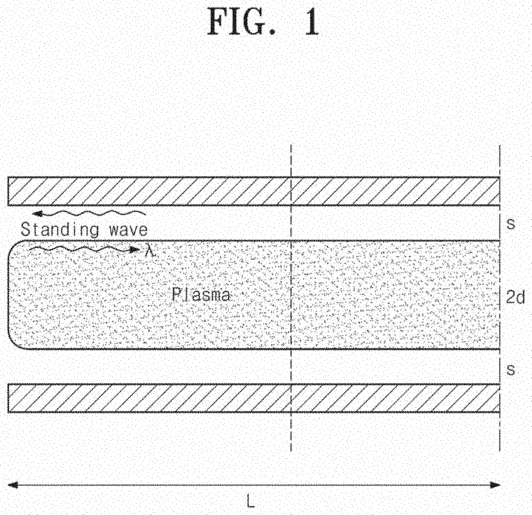

Referring to FIG. 1, a substrate processing apparatus 10 processes a substrate W by using plasma. For example, the substrate processing apparatus 10 may perform an etching process on the substrate W. The substrate processing apparatus 10 may include a chamber 100, a support unit 200 (an example of a lower electrode unit), a gas supply unit 300, an upper electrode unit 400, a temperature control unit 500, a power unit 600, a ring unit 700, a harmonic control unit 800, and a controller 900.

The chamber 100 may have an inner space 101. The substrate W may be processed in the inner space 101. In the inner space 101, the substrate W may be processed by plasma. The substrate W may be etched by plasma. The plasma may be transferred to the substrate W to etch a layer formed on the substrate W.

An inner wall of the chamber 100 may be coated with a material having excellent plasma resistance. The chamber 100 may be grounded. An entrance (not shown) through which the substrate W can be carried in or out may be formed in the chamber 100. The entrance may be selectively opened and closed by a door (not shown). While the substrate W is processed, the inner space 101 may be closed by the entrance. In addition, while the substrate W is processed, the inner space 101 may have a vacuum pressure atmosphere.

An exhaust hole 102 may be formed at the bottom of the chamber 100. The atmosphere of the inner space 101 may be exhausted through the exhaust hole 102. The exhaust hole 102 may be connected to an exhaust line VL for reducing pressure in the inner space 101. Process gas, plasma supplied to the inner space 101, and process by-products may be exhausted to the outside of the substrate processing apparatus 10 through the exhaust hole 102 and the exhaust line VL. In addition, the pressure in the inner space 101 may be adjusted by the reduced pressure provided by the exhaust line VL. For example, the pressure of the inner space 101 may be adjusted by the reduced pressure provided by the gas supply unit 300 and the exhaust line VL, which will be described later. When the pressure of the inner space 101 is to be lowered, the reduced pressure provided by the exhaust line VL may be increased or the supply amount of the process gas supplied by the gas supply unit 300 per unit time may be reduced. To the contrary, when the pressure of the inner space 101 is to be further increased, the reduced pressure provided by the exhaust line VL may be reduced or the supply amount of the process gas supplied by the gas supply unit 300 per unit time may be increased.

The support unit 200 may support the substrate W. The support unit 200 may support the substrate W in the inner space 101. The support unit 200 may have one of opposite electrodes forming an electric field in the inner space 101. In addition, the support unit 200 may be an electrostatic chuck (ESC) capable of adsorbing and fixing the substrate W by using electrostatic force.

The support unit 200 may include a dielectric plate 210, an electrostatic electrode 220, a heater 230, a lower electrode 240, and an insulating plate 250.

The dielectric plate 210 may be provided over the support unit 200. The dielectric plate 210 may be formed of an insulating material. For example, the dielectric plate 210 may be made of a material including ceramic or quartz. The dielectric plate 210 may have a seating surface supporting the substrate W. When the dielectric plate 210 is viewed from the top, the seating surface may have an area smaller than that of the lower surface of the substrate W. A lower surface of the edge area of the substrate W placed on the dielectric plate 210 may face an upper surface of an edge ring 710 to be described later.

A first supply passage 211 is formed in the dielectric plate 210. The first supply passage 211 may extend from the upper surface to the lower surface of the dielectric plate 210. A plurality of first supply passages 211 may be formed spaced apart from each other, and may be provided as passages through which a heat transfer medium is supplied to the lower surface of the substrate W. For example, the first supply passage 211 may be in fluid communication with a first circulation passage 241 and a second supply passage 243 to be described later.

In addition, a separate electrode (not shown) for adsorbing the substrate W to the dielectric plate 210 may be embedded in the dielectric plate 210. A direct current may be applied to the electrode. An electrostatic force may act between the electrode and the substrate by the applied current, and the substrate W may be adsorbed to the dielectric plate 210 by the electrostatic force.

The electrostatic electrode 220 may chuck the substrate W by generating electrostatic force. The electrostatic electrode 220 may be provided within the dielectric plate 210. The electrostatic electrode 220 may be embedded in the dielectric plate 210. The electrostatic electrode 220 may be electrically connected to an electrostatic power source 221. The electrostatic power source 221 may selectively chuck the substrate W by applying power to the electrostatic electrode 220.

The heater 230 is electrically connected to an external power source (not shown). The heater 230 generates heat by resisting a current applied from an external power source. The generated heat is transferred to the substrate W through the dielectric plate 210. The substrate W is maintained at a predetermined temperature by the heat generated by the heater 230. The heater 230 includes a spiral coil. The heaters 230 may be embedded in the dielectric plate 210 at regular intervals.

The lower electrode 240 is positioned below the dielectric plate 210. The lower electrode 240 may be an electrode that forms an electric field in the inner space 101. The lower electrode 240 may be one of opposite electrodes that form an electric field in the inner space 101. The lower electrode 240 may be provided to face an upper electrode 420 to be described later, which is another one of the opposite electrodes. The electric field formed in the inner space 101 by the lower electrode 240 may excite a process gas supplied from the gas supply unit 300 to be described later, thereby generating plasma. The lower electrode 240 may be provided within the dielectric plate 210.

The upper surface of the lower electrode 240 may be stepped so that the central area is positioned higher than the edge area. The central area of the upper surface of the lower electrode 240 has an area corresponding to the bottom surface of the dielectric plate 210 and is bonded to the bottom surface of the dielectric plate 210. The first circulation passage 241, a second circulation passage 242, and the second supply passage 243 may be formed in the lower electrode 240.

The first circulation passage 241 is provided as a passage through which the heat transfer medium is circulated. The heat transfer medium stored in a heat transfer medium storage unit GS may be supplied to the first circulation passage 241 through a medium supply line GL. A medium supply valve GB may be installed in the medium supply line GL. According to the on/off of the medium supply valve GB or the change in an opening rate, it is possible to control the heat transfer medium to be supplied to the first circulation passage 241 or the supply flow rate per unit time of the heat transfer medium supplied to the first circulation passage 241. The heat transfer medium may include helium (He) gas.

The first circulation passage 241 may be formed in a spiral shape inside the lower electrode 240. Alternatively, in the first circulation passage 241, ring-shaped passages having different radii may be arranged to be concentric. The first circulation passages 241 may communicate with each other. The first circulation passages 241 are formed at the same height.

The second circulation passage 242 is provided as a passage through which the cooling fluid circulates. The cooling fluid stored in a cooling fluid storage unit CS may be supplied to the second circulation passage 242 through a fluid supply line CL. A fluid supply valve CB may be installed in the fluid supply line CL. According to the on/off of the fluid supply valve CB or the change in an opening rate, it is possible to control the cooling fluid to be supplied to the second circulation passage 242 or the supply flow rate per unit time of the cooling fluid supplied to the second circulation passage 242. The cooling fluid may be cooling water or cooling gas. The cooling fluid supplied to the second circulation passage 242 may cool the lower electrode 240 to a predetermined temperature. The lower electrode 240 cooled to a predetermined temperature may maintain the temperature of the dielectric plate 210 and/or the substrate W at a predetermined temperature.

The second circulation passage 242 may be formed in a spiral shape inside the lower electrode 240. Alternatively, in the second circulation passage 242, ring-shaped passages having different radii may be arranged to be concentric. The second circulation passages 242 may communicate with each other. The second circulation passage 242 may have a larger cross-sectional area than the first circulation passage 241. The second circulation passages 242 are formed at the same height. The second circulation passage 242 may be located below the first circulation passage 241.

The second supply passage 243 extends upward from the first circulation passage 241 and is provided to the upper surface of the lower electrode 240. The second supply passage 243 is provided in a number corresponding to the first supply passage 211, and allows the first circulation passage 241 and the first supply passage 211 to be in fluid communication with each other.

The insulating plate 250 is provided under the lower electrode 240. The insulating plate 250 is provided in a size corresponding to the lower electrode 240. The insulating plate 250 is positioned between the lower electrode 240 and the bottom surface of the chamber 100. The insulating plate 250 may be formed of an insulating material and may electrically insulate the lower electrode 240 from the chamber 100.

The gas supply unit 300 supplies a process gas to the chamber 100. The gas supply unit 300 includes a gas storage unit 310, a gas supply line 320, and a gas inlet port 330. The gas supply line 320 connects the gas storage unit 310 and the gas inlet port 330 and supplies process gas stored in the gas storage unit 310 to the gas inlet port 330. The gas inlet port 330 may be installed in a gas supply hole 422 formed in the upper electrode 420.

The upper electrode unit 400 may have the upper electrode 420 facing the lower electrode 240. In addition, the gas supply unit 300 described above may be connected to the upper electrode unit 400 to provide a part of a supply path of process gas supplied from the gas supply unit 300. The upper electrode unit 400 may include a support body 410, the upper electrode 420 and a distribution plate 430.

The support body 410 may be fastened to the chamber 100. The support body 410 may be a body to which the upper electrode 420 and the distribution plate 430 of the upper electrode unit 400 are fastened. The support body 410 may be a medium through which the upper electrode 420 and the distribution plate 430 are installed in the chamber 100.

The upper electrode 420 may be an electrode facing the lower electrode 240. The upper electrode 420 may be provided to face the lower electrode 240. An electric field may be formed in a space between the upper electrode 420 and the lower electrode 240. The formed electric field may generate plasma by exciting process gas supplied to the inner space 101. The upper electrode 420 may be provided in a disk shape. The upper electrode 420 may include an upper plate 410a and a lower plate 410b. The upper electrode 420 may be grounded. However, the embodiment is not limited thereto, and an RF power source (not shown) may be connected to the upper electrode 420 to apply an RF voltage.

The bottom surface of the upper plate 412a is stepped so that the central area is higher than the edge area. Gas supply holes 422 are formed in the central area of the upper plate 420a. The gas supply holes 422 are connected to the gas inlet port 330 and supply process gas to a buffer space 424. A cooling passage 421 may be formed inside the upper plate 410a. The cooling passage 421 may be formed in a spiral shape. Alternatively, in the cooling passage 421, ring-shaped passages having different radii may be arranged to be concentric. The temperature control unit 500 to be described later may supply a cooling fluid to the cooling passage 421. The supplied cooling fluid may circulate along the cooling passage 421 to cool the upper plate 420a.

The lower plate 420b is located below the upper plate 420a. The lower plate 420b is provided in a size corresponding to the upper plate 420a and is located to face the upper plate 420a. The upper surface of the lower plate 410b is stepped so that the central area is located lower than the edge area. The upper surface of the lower plate 420b and the lower surface of the upper plate 420a are combined with each other to form the buffer space 424. The buffer space 424 is provided as a space where the gas supplied through the gas supply holes 422 temporarily stays before being supplied into the chamber 100. Gas supply holes 423 are formed in the central area of the lower plate 420b. A plurality of gas supply holes 423 are spaced apart at regular intervals. The gas supply holes 423 are connected to the buffer space 424.

The distribution plate 430 is located under the lower plate 420b. The distribution plate 430 is provided in a disk shape. Distribution holes 431 are formed in the distribution plate 430. The distribution holes 431 are provided from the upper surface to the lower surface of the distribution plate 430. The distribution holes 431 are provided in a number corresponding to the gas supply holes 423, and are located corresponding to the positions where the gas supply holes 423 are located. The process gas staying in the buffer space 424 is uniformly supplied into the chamber 100 through the gas supply hole 423 and the distribution holes 431.

The temperature control unit 500 may control the temperature of the upper electrode 420. The temperature control unit 500 may include a heating member S11, a heating power source 513, a filter 515, a cooling fluid supply unit 521, a fluid supply channel 523, and a valve 525.

The heating member S11 may heat the lower plate 420b. The heating member S11 may be a heater. The heating member S11 may be a resistive heater. The heating member S11 may be embedded in the lower plate 420b. The heating power source 513 may generate power for allowing the heating member S11 to generate heat. The heating power source 513 may heat the lower plate 420b by generating heat from the heating member S11. The heating power source 513 may be a DC power source. The filter 515 may block transmission of the RF voltage (power) applied by the power unit 600 to be described later to the heating power source 513.

The cooling fluid supply unit 521 may store a cooling fluid for cooling the upper plate 520a. The cooling fluid supply unit 521 may supply the cooling fluid to the cooling passage 421 through the fluid supply channel 523. The cooling fluid supplied to the cooling passage 421 may lower the temperature of the upper plate 420a while flowing along the cooling passage 421. In addition, the fluid valve 525 may be installed in the fluid supply channel 523 to control whether the cooling fluid is supplied to the cooling fluid supply unit 521 or the supply amount of the cooling fluid per unit time. The fluid valve 525 may be an on/off valve or a flow control valve.

The power unit 600 may apply a radio frequency (RF) voltage to the lower electrode 240. The power unit 600 may apply an RF voltage to the lower electrode 240 to form an electric field in the inner space 101. The electric field formed in the inner space 101 may excite process gas supplied to the inner space 101 to generate plasma. The power unit 600 may include a first power source 610, a second power source 620, a third power source 630, and a matching member 640.

The first power source 610 may apply a voltage having a first frequency to the lower electrode 240. The first frequency of the voltage generated by the first power source 610 may be higher than the second frequency and the third frequency of the voltages generated by the second power source 620 and the third power source 630 described below. The first power source 610 may be a source RF for generating plasma in the inner space 101. The first frequency may be 60 MHz.

The first power source 610 may be configured to apply a first sustaining voltage having a first frequency or a first pulse voltage having a first frequency to the lower electrode 240. The first sustaining voltage may be continuous wave (CW) RF. In addition, the first pulse voltage may be a pulsed RF.

The second power source 620 may apply a voltage having a second frequency to the lower electrode 240. The second frequency of the voltage generated by the second power source 620 is lower than the first frequency of the voltage generated by the first power source 610 and higher than the third frequency of the voltage generated by the third power source 630. The second power source 620 may be a source RF that generates plasma in the inner space 101 together with the first power source 610. The second frequency may be 2 MHz to 9.8 MHz.

The second power source 620 may be configured to apply a second sustaining voltage having a second frequency or a second pulse voltage having a second frequency to the lower electrode 240. The second sustaining voltage may be continuous wave (CW) RF. In addition, the second pulse voltage may be a pulsed RF.

The third power source 630 may apply a voltage having a third frequency to the lower electrode 240. The third frequency of the voltage generated by the third power source 630 may be lower than the first frequency of the voltage generated by the first power source 610 and the second frequency generated by the second power source 620. The second power source 620 may be a bias RF used to accelerate plasma ions in the inner space 101 together with the first power source 610. The third frequency may be 40 kHz.

The third power source 630 may be configured to apply a third sustaining voltage having the third frequency or a third pulse voltage having the third frequency to the lower electrode 240. The third sustaining voltage may be a continuous wave (CW) RF. In addition, the third pulse voltage may be a pulsed RF.

The matching member 640 may perform impedance matching. The matching member 640 may be connected to the first power source 610, the second power source 620 and the third power source 630, and the first power source 610, the second power source 620 and the third power source 630 may perform impedance matching with respect to the voltage applied to the lower electrode 240.

The ring unit 700 may be arranged in an edge area of the support unit 200. The ring unit 700 may include the edge ring 710, an insulating body 720 and a coupling ring 730.

The edge ring 710 may be disposed below the edge area of the substrate W. At least a portion of the edge ring 710 may be disposed below the edge area of the substrate W. The edge ring 710 may have a ring shape as a whole. The upper surface of the edge ring 710 may include an inner upper surface, an outer upper surface, and an inclined upper surface. The inner upper surface may be an upper surface adjacent to the central area of the substrate W. The outer upper surface may be an upper surface farther from the central area of the substrate W than the inner upper surface. The inclined upper surface may be an upper surface provided between the inner upper surface and the outer upper surface. The inclined upper surface may be an upper surface inclined upward in a direction away from the center of the substrate W. The edge ring 710 may expand an electric field forming area such that the substrate W is positioned at the center of the area where plasma is formed. The edge ring 710 may be a focus ring. The edge ring 710 may be made of a material including Si or SiC.

The insulating body 720 may be configured to surround the edge ring 710 when viewed from the top. The insulating body 720 may be made of an insulating material. The insulating body 720 may be provided to include a material such as quartz or ceramic.

A harmonic control line EL may be connected to the coupling ring 730. The coupling ring 730 may be disposed under the edge ring 710 and the insulating body 720. The coupling ring 730 may be surrounded by the edge ring 710, the insulating body 720, the lower electrode 240 and the dielectric plate 210. The coupling ring 710 may include a ring body 731 and a ring electrode 732 (one example of a conductive component). The ring body 731 may be formed of an insulating material. For example, the ring body 731 may be made of an insulating material such as quartz or ceramic. The ring body 731 may be configured to surround the ring electrode 732. The ring electrode 732 may be formed of a conductive material such as a material including metal. In addition, the ring electrode 732 may be electrically connected to the harmonic control unit 800 through a harmonic control line EL. Accordingly, harmonic components that may be generated in the inner space 101 may be input to the harmonic control unit 800 through the harmonic control line EL.

The harmonic control unit 800 may control harmonics generated by RF power applied from the power unit 600 to the lower electrode 240. The harmonic control unit 800 may remove harmonic components in the electric field generated in the inner space 101. The electric field generated in the inner space 101 may be electrically coupled with the ring electrode 732.

The harmonic control unit 800 may remove harmonics that may occur due to nonlinearity of plasma generated when the power unit 600 applies the RF power to the lower electrode 240. The harmonic control unit 800 may be provided between the ground “G” (grounding part) and the ring electrode 732. Harmonic components flowing into the harmonic control unit 800 may be removed through the ground “G”. In other words, the harmonic control unit 800 may provide a removal path through which harmonic components are removed.

The harmonics that may be removed by the harmonic control unit 800 may include the second harmonic, the third harmonic, and the fourth through n-th harmonics. The n-th harmonic may have a frequency that is an integer multiple of the first frequency of the voltage applied by the first power source 610. Alternatively, the n-th harmonic may have a frequency that is an integer multiple of the second frequency of the voltage applied by the second power source 620. For example, the second harmonic among the harmonics may have a frequency twice as high as the first frequency, which may be the main frequency. For example, when the first frequency is 60 MHz, the second harmonic may be 120 MHz. In addition, the third harmonic wave may be 180 MHz. The fourth harmonic may be 240 MHz. The n-th harmonic may have a frequency of (60×n) MHz (where n is a natural number).

A specific configuration of the harmonic control unit 800 will be described later.

The controller 900 may control the substrate processing apparatus 10. The controller 900 may control components of the substrate processing apparatus 10. The controller 900 may control the substrate processing apparatus 10 to perform a harmonic control method described later.

The controller 900 may include a process controller including a microprocessor (computer) that controls the substrate processing apparatus 10, a user interface including a keyboard through which an operator inputs commands and the like to manage the substrate processing apparatus 10 and a display which visually displays an operating situation of the substrate processing apparatus, and a storage unit that stores a control program for executing a process executed in the substrate processing apparatus 10 under the control of a process controller, or a program for executing a process in each component unit according to various data and process conditions, that is, a process recipe. In addition, the user interface and storage unit may be connected to the process controller. The processing recipe may be stored in a storage medium of the storage unit, and the storage medium may be a hard disk, a portable disk such as a CD-ROM or a DVD, or a semiconductor memory such as a flash memory.

FIG. 3 is a diagram schematically illustrating the harmonic control unit of FIG. 2. Referring to FIG. 3, the harmonic control unit 800 may include a blocking unit 810 and a removal unit 820. The blocking unit 810 may block the frequency component of the RF power from flowing toward the ground G. The removal unit 820 is provided between the blocking unit 810 and the ground G, and can remove harmonic components of the plasma.

The blocking unit 810 may block the frequency component of the RF power applied to the lower electrode 240 by the power unit 600 from flowing to the ground “G”. The blocking unit 810 may include a first blocking filter 812, a second blocking filter 814, and a third blocking filter 816.

The first blocking filter 812 may block a current having a first frequency component of a voltage applied by the first power source 610 from flowing to the ground “G”. The first blocking filter 812 may be a band rejection filter. However, the embodiment is not limited thereto and the first blocking filter 812 may be implemented with a combination of known filters. The first blocking filter 812 may block a current having a frequency band including the first frequency from flowing to the ground G.

The second blocking filter 814 may block a current having a second frequency component of a voltage applied by the second power source 620 from flowing to the ground G. The second blocking filter 814 may be a band rejection filter. However, the embodiment is not limited thereto and the second blocking filter 814 may be implemented with a combination of known filters. The second blocking filter 814 may block a current having a frequency band including the second frequency from flowing to the ground G.

The third blocking filter 816 may block a current having the third frequency component of the voltage applied by the third power source 630 from flowing to the ground G. The third blocking filter 816 may be a band rejection filter. However, the embodiment is not limited thereto and the third blocking filter 816 may be implemented with a combination of known filters. The third blocking filter 816 may block a current having a frequency band including the second frequency from flowing to the ground G.

That is, the blocking unit 810 of the inventive concept may minimize loss of the RF power applied to the lower electrode 240 by the power unit 600 as the RF power flows into the harmonic control unit 800. In other words, the RF power component of the electric wave formed in the inner space 101 by the harmonic control unit 800 is not removed, and helps only the harmonic component to be selectively removed.

The removal unit 820 may remove harmonic components. The removal unit 820 may be provided between the blocking unit 810 and the ground G to remove harmonic components. The removal unit may include a first harmonic removal unit 821, a second harmonic removal unit 822, a third harmonic removal unit 823, a fourth harmonic removal unit 824, and a fifth harmonic removal unit 825. The first harmonic removal unit 821 may include a first blocking filter 821a and a first harmonic control circuit 821b. The second harmonic removal unit 822 may include a second blocking filter 822a and a second harmonic control circuit 822b. The third harmonic removal unit 823 may include a third blocking filter 823a and a third harmonic control circuit 823b. The fourth harmonic removal unit 824 may include a fourth blocking filter 824a and a fourth harmonic control circuit 824b. The fifth harmonic removal unit 825 may include a fifth blocking filter 825a and a fifth harmonic control circuit 825b.

The first to fifth harmonic removal units 821 to 825 may have different removable harmonic components, respectively. For example, the first harmonic removal unit 821 may be configured to remove the p-th harmonic (where p is a natural number). The second harmonic removal unit 822 may be configured to remove the q-th harmonic (where q is a natural number). The q-th harmonic may be different from the p-th harmonic.

For example, the first harmonic removal unit 821 may be configured to remove the second harmonic. Also, the second harmonic removal unit 822 may be configured to remove the third harmonic. In addition, the third harmonic removal unit 823 may be configured to remove the fourth harmonic. In addition, the fourth harmonic removal unit 824 may be configured to remove the fifth harmonic. In addition, the fifth harmonic removal unit 825 may be configured to remove the sixth harmonic.

The first to fifth harmonic removal units 821 to 825 may have substantially the same/similar structures. Accordingly, in the following description, the first harmonic removal unit 821 will be mainly described, and repeated descriptions will be omitted.

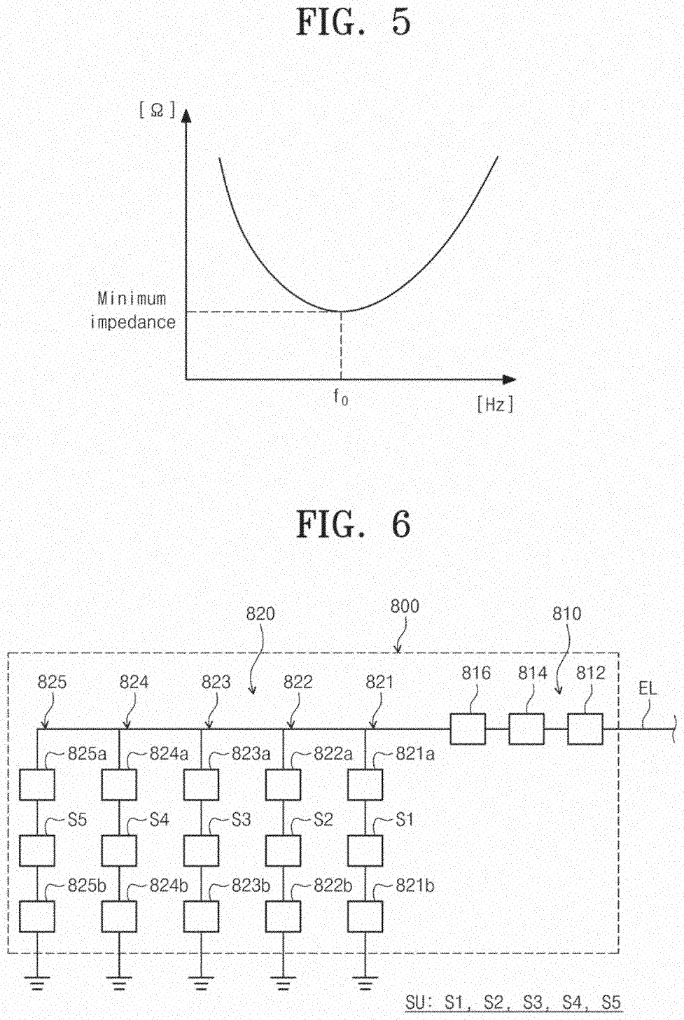

The first harmonic removal unit 821 may include a first blocking filter 821a and a first harmonic control circuit 821b. The first blocking filter 821a may be configured to block frequency components other than the frequency component of the p-th harmonic (e.g., second harmonic) among the harmonic components. The first blocking filter 821a may be a band pass filter. However, the embodiment is not limited thereto and the first blocking filter 821a may be composed of a combination of known filters. All other frequency components other than the p-th harmonic are blocked by the first blocking filter 821a, and only the current of the frequency component of the p-th harmonic may flow to the first harmonic control circuit 821b. The first harmonic control circuit 821b may be a circuit including a first inductor L1 and a first capacitor C1 that is a variable capacitor. In this case, the controller 900 may control the capacitance of the first capacitor C1 such that the first harmonic control circuit 821b becomes a resonance circuit. For example, as shown in FIG. 5, the capacitance of the first capacitor C1 may be adjusted such that the resonant frequency f0 of the first harmonic control circuit 821b becomes the frequency of the p-th harmonic. That is, the first harmonic control circuit 821b may be a resonance circuit at the frequency of the p-th harmonic. In this case, the magnitude of the impedance of the first harmonic control circuit 821b may be minimized, and in this case, the current of the frequency component of the p-th harmonic flowing through the first harmonic control circuit 821b may flow at the maximum.

The remaining frequency components other than the frequency component of the p-th harmonic may be blocked by the first blocking filter 821a, and the current having the frequency component of the p-th harmonic may flow at the maximum in the first harmonic control circuit 821b to ground G to be removed. Thus, the frequency component of the p-th harmonic may be effectively removed.

Similarly, the second harmonic removal unit 822 includes a second blocking filter 822a for blocking the remaining frequency components except for the frequency components of the q-th harmonic (e.g., the third harmonic) different from the p-th harmonic, and a second harmonic control circuit 822b provided between the second blocking filter 822a and the ground G. Similar to the first harmonic control circuit 821b, the second harmonic control circuit 822b may be a circuit including a second inductor and a second capacitor. The controller 900 may adjust the capacitance of the second capacitor such that the second harmonic control circuit 822b becomes a resonance circuit for the frequency of the q-th harmonic.

Similarly, the third harmonic removal unit 823 may include the third blocking filter 823a and the third harmonic control circuit 823b. The fourth harmonic removal unit 824 may include the fourth blocking filter 824a and the fourth harmonic control circuit 824b. The fourth harmonic removal unit 824 may include the fourth blocking filter 824a and the fourth harmonic control circuit 824b. The n-th harmonic controller 82n may include an n-th blocking filter 82na and an n-th harmonic control circuit 82nb (where n is a natural number).

That is, in the harmonic control unit 800 according to an embodiment of the inventive concept, among the components of the electrical wave of the electric field generated in the inner space 101, the component due to the voltage applied by the power unit 600 is blocked from being removed by the harmonic control unit 800, but may be configured to remove various harmonics. Thus, harmonic components may be effectively removed.

A method of controlling harmonics according to an embodiment of the inventive concept may include the following operations.

First, the blocking unit 810 of the harmonic control unit 800 connected to the ring unit 700 disposed on the edge area of the support unit 200 supporting the substrate W may block the frequency component of the RF power applied by the power unit 600 from flowing to the ground G. When the power unit 600 applies the RF power to the lower electrode 240, the applied power forms an electric field in the inner space 101. The electric field may be an electrical wave. The electrical wave may include a component generated by power applied by the power unit 600 and a harmonic component that may be generated for various reasons. The electric field may be coupled with the ring electrode 732 of the ring unit 700.

Second, harmonics passing through the blocking unit 810 may be removed through the removal unit of the harmonic control unit 800. In the operation of removing harmonics, blocking filters may block frequency components other than frequency components of harmonics, and harmonics may be removed through a harmonic control circuit having a variable capacitor. In this case, the variable capacitor of the harmonic control circuit may be adjusted to more effectively remove harmonic components.

In addition, in the operation of removing harmonics, the first to fifth blocking filters 821a to 825a may block the remaining frequency components except for the frequency components of the harmonics assigned to each, and the capacitance of the variable capacitor of the first to fifth harmonic control circuits 821b to 825b may be adjusted to become a resonance circuit at the frequency of each assigned harmonic.

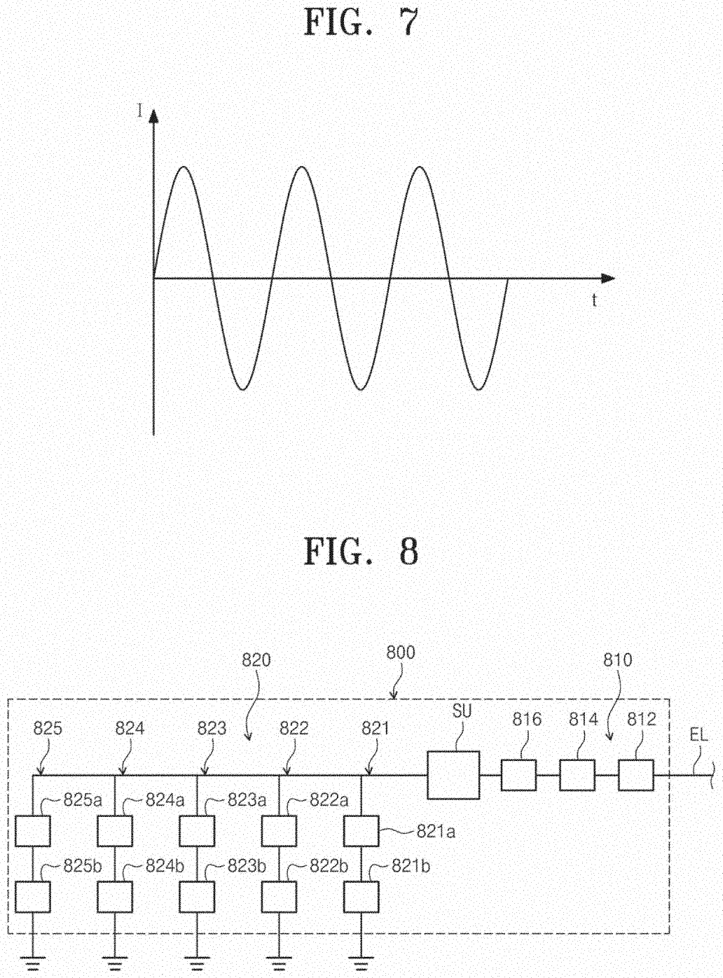

FIG. 6 is a diagram schematically illustrating the appearances of a harmonic control unit and a detection unit of a substrate processing apparatus according to another embodiment of the inventive concept. FIG. 7 is a graph illustrating changes in current of harmonic components detected by the detection unit of FIG. 6.

Referring to FIGS. 6 and 7, a substrate processing apparatus according to an embodiment of the inventive concept may further include a detection unit SU. The detection unit SU may detect a voltage or current flowing through the harmonic control unit 800. The detection unit SU may include a first detection member S1, a second detection member S2, a third detection member S3, a fourth detection member S4, and a fifth detection member S5. The first to fifth detection members S1 to S5 may be ammeters or voltmeters. The electronic outputs detected by the first to fifth detection members S1 to S5 may be transmitted to the controller 900. The controller 900 may adjust the capacitance of the variable capacitors (e.g., first to fifth capacitors) of the harmonic control unit 800 based on the voltage or current value measured by the detection unit SU. For example, the controller 900 may adjust capacitances of variable capacitors (e.g., first to fifth capacitors) such that the magnitude of the current detected by the detection unit SU is maximized.

In the above-described example, the detection unit SU is provided between the blocking filters 821a to 825a and the harmonic control circuits 821b to 825b, but the embodiment is not limited thereto. For example, the detection unit SU may include an ammeter or a voltmeter, and may also be provided between the blocking unit 810 and the removal unit 820.

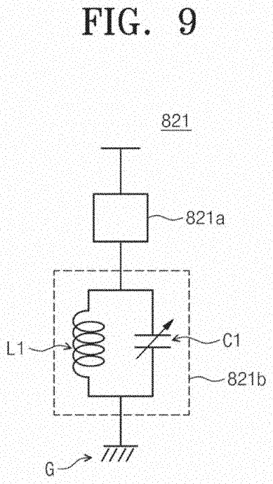

In the above example, inductors and capacitors constituting the harmonic control circuits 821b to 825b connected in series have been described, but the embodiment is not limited thereto. For example, as shown in FIG. 9, inductors and capacitors constituting the harmonic control circuits 821b to 825b may be connected in parallel.

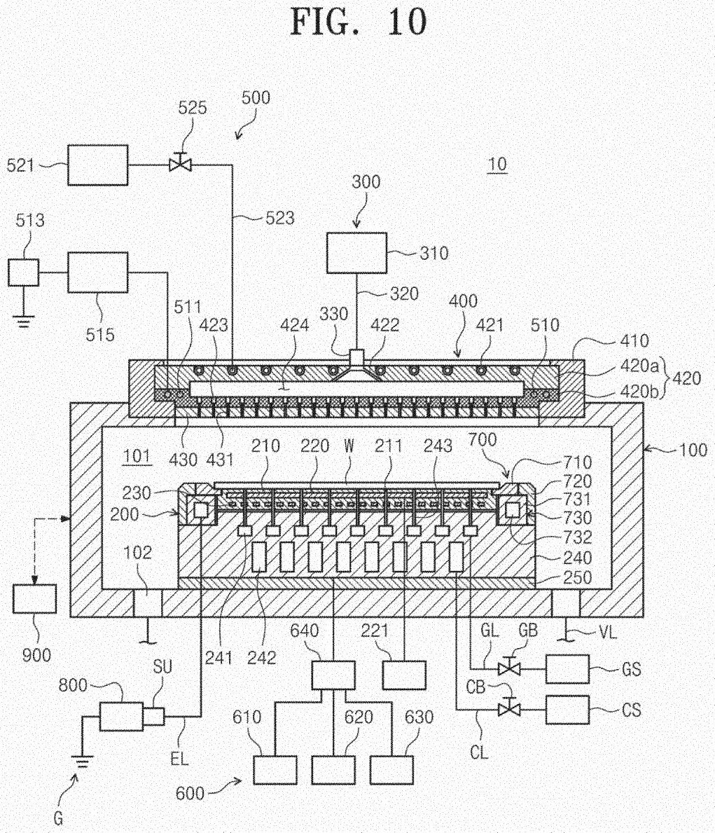

In the above example, it has been described that the detection unit SU is electrically arranged between components of the harmonic control unit 800, but the embodiment is not limited thereto. For example, as shown in FIG. 10, the detection unit SU may be disposed between the ring unit 700 and the harmonic control unit 800.

According to an embodiment of the inventive concept, a substrate may be efficiently processed.

In addition, according to an embodiment of the inventive concept, it is possible to improve substrate processing uniformity by plasma.

In addition, according to an embodiment of the inventive concept, it is possible to obtain both advantages of generating plasma using continuous wave RF and advantages of generating plasma using pulsed RF.

In addition, according to an embodiment of the inventive concept, it is possible to produce the object etched by the plasma in a substantially vertical shape.

In addition, according to an embodiment of the inventive concept, when plasma is generated using a pulse voltage, it is possible to improve the uniformity of the density of plasma generated according to the area of a substrate.

Effects of the inventive concept may not be limited to the above, and other effects of the inventive concept will be clearly understandable to those having ordinary skill in the art from the disclosures provided below together with accompanying drawings.

Since the above embodiments are presented to help the understanding of the inventive concept, it should be understood that they do not limit the scope of the inventive concept and various variations thereto also belong to the scope of the inventive concept. For example, each component described to be of a single type may be implemented in a distributed manner Likewise, components described to be distributed may be implemented in a combined manner Therefore, the technical protective scope of the inventive concept should be defined by the technical spirit of the following claims and it should be understood that the technical protective scope of the inventive concept is not limited to the wording of the claims but actually reaches inventions having equivalent technical values.

1. A substrate processing apparatus comprising:
a chamber having an inner space;
a support unit configured to support a substrate in the inner space;
a ring unit disposed on an edge area of the support unit when viewed from above;
a power unit configured to generate RF power for forming an electric field in the inner space; and
a harmonic control unit connected to the ring unit to control harmonics generated by the RF power.

2. The substrate processing apparatus of claim 1, wherein the ring unit includes:
an edge ring disposed to overlap an edge area of the substrate supported by the support unit when viewed from above; and
a coupling ring disposed below the edge ring, and
wherein the harmonic control unit is connected to the coupling ring.

3. The substrate processing apparatus of claim 2, wherein the coupling ring includes:
a ring electrode; and
a ring body formed of an insulating material and surrounding at least a portion of the ring electrode,
wherein the harmonic control unit is electrically connected to the ring electrode.

4. The substrate processing apparatus of claim 1, wherein the harmonic control unit includes:
a blocking unit configured to block a frequency component of the RF power from flowing toward a ground; and
a removal unit provided between the blocking unit and the ground to remove the harmonics.

5. The substrate processing apparatus of claim 4, wherein the removal unit includes:
a first blocking filter configured to block frequency components other than a frequency component of a p-th harmonic among the harmonics; and
a first harmonic control circuit provided between the first blocking filter and the ground.

6. The substrate processing apparatus of claim 5, wherein the removal unit includes:
a second blocking filter configured to block frequency components other than a frequency component of a q-th harmonic different from the p-th harmonic, among the harmonics; and
a second harmonic control circuit provided between the second blocking filter and the ground.

7. The substrate processing apparatus of claim 6, wherein the first harmonic control circuit includes a first inductor and a first capacitor, and
the second harmonic control circuit includes a second inductor and a second capacitor.

8. The substrate processing apparatus of claim 7, further comprising:
a controller configured to control the harmonic control unit,
wherein the first capacitor and the second capacitor are variable capacitors, and
wherein the controller is configured to adjust capacitances of the first capacitor and the second capacitor to allow the first harmonic control circuit to constitute a resonance circuit at a frequency of the p-th harmonic and allow the second harmonic control circuit to constitute a resonance circuit at a frequency of the q-th harmonic.

9. The substrate processing apparatus of claim 8, further comprising:
a detection unit configured to detect a voltage or current flowing toward or to the harmonic control unit.

10. The substrate processing apparatus of claim 9, wherein the controller is configured to adjust at least one of the capacitances of the first capacitor and the second capacitor based on the voltage or current measured by the detection unit.

11. The substrate processing apparatus of claim 4, wherein the power unit includes:
a first power source configured to apply a first voltage having a first frequency to an electrode forming the electric field;
a second power source configured to apply a second voltage having a second frequency lower than the first frequency to the electrode; and
a third power source configured to apply a third voltage having a third frequency lower than the first frequency and the second frequency to the electrode.

12. The substrate processing apparatus of claim 11, wherein the blocking unit includes:
a first blocking filter configured to block a first frequency component of the first voltage;
a second blocking filter configured to block a second frequency component of the second voltage; and
a third blocking filter configured to block a third frequency component of the third voltage.

13. A harmonic control unit that controls harmonics generated in a substrate processing apparatus and is connected to a conductive component, wherein the substrate processing apparatus includes an electrode that forms an electric field and the conductive component that is installed at a location different from a location of the electrode, the harmonic control unit comprising:
a blocking unit configured to block a frequency component of RF power from flowing to a ground, the frequency component of the RF power forming the electric field among frequency components flowing into the harmonic control unit; and
a removal unit provided between the blocking unit and the ground to remove the harmonics.

14. The harmonic control unit of claim 13, wherein the removal unit includes:
a first harmonic removal unit; and
a second harmonic removal unit configured to remove a frequency component different from a frequency component of the first harmonics removal unit.

15. The harmonic control unit of claim 14, wherein the first harmonic removal unit includes:
a first blocking filter configured to block frequency components other than a frequency component of a p-th harmonic among the harmonics; and
a first harmonic control circuit provided between the first blocking filter and the ground,
wherein the second harmonic removal unit includes:
a second blocking filter configured to block frequency components other than a frequency component of a q-th harmonic different from the p-th harmonic, among the harmonics; and
a second harmonic control circuit provided between the second blocking filter and the ground.

16. The harmonic control unit of claim 15, wherein the first harmonic control circuit and the second harmonic control circuit include a first capacitor and a second capacitor, respectively,
wherein the first capacitor and the second capacitor are variable capacitors, and
wherein capacitances of the first capacitor and the second capacitor are adjusted to allow the first harmonic control circuit to constitute a resonance circuit at a frequency of the p-th harmonic and allow the second harmonic control circuit to constitute a resonance circuit at a frequency of the q-th harmonic.

17.-20. (canceled)
